(19) United States
(12) Patent Application Publication
(10) Pub. No.: US 2005/0046430 A1
(43) Pub. Date: Mar. 3, 2005

(54) RF testing method and arrangement

(76) Inventors: Jouko Kinnunen, Pattijoki (FI); Heikki Nykanen, Tampere (FI); Juha Valtanen, Oulu (FI); Mikko Kursula, Oulu (FI)

Correspondence Address: Finnegan, Henderson, Farabow,;Garrett & Dunner, L.L.P., 1300 I Street, N.W., Washington, DC, 20005-3315, US

(21) Appl. No.: 10/653,203

(22) Filed: Sep. 3, 2003

(51) Int. Cl. G01R 31/302

(52) U.S. Cl. 324/750

(57) ABSTRACT

An RF testing method and arrangement of an electronic device utilize sensors for measuring the electronic device under test in conjunction with production of the electronic devices. A comparator performs a comparison between measurement signals and corresponding reference signals from a reference supply and a decision unit determines defectiveness of the electronic device based on the comparison.

### FIELD

The invention relates to RF testing of an electronic device in conjunction with the production.

### BACKGROUND

Testing an electronic device, for example such as a mobile phone, is of vital importance for ensuring delivery of a correctly operable device to a customer. One of the most important properties to test is the RF operation (Radio Frequency). A test can be performed on a complete electronic device at the end of the production line, or a circuit board or a component can be tested separately. During testing, measurement signals from the electronic device are recorded and the measurement signals are then analysed using various analysis algorithms to observe whether the values of the measurement signals fall within desired limits, which are usually manually fed to the testing system. If the values of the measurement signals stay within the limits, the electronic device is acceptable independent of the variation of the measurement signals within the limits. If the limits are not met, the electronic device is not acceptable. The analysis usually uses various measurement signals to ensure a proper operation and condition of the electronic device.

There are, however, problems related to the testing. The analysis is slow and it has to be carried out after the measurements. Although the testing systems can be rather complex, the versatility is limited and analysis requires a lot of processing power, which unnecessarily increases the delay in receiving the results from the test. Further, since the analysis does not properly take into account the forms of the measurement signals, pieces of information are lost and certain latent defects may be difficult to detect or they may remain completely undetected.

### BRIEF DESCRIPTION OF THE INVENTION

An object of the invention is to provide an improved testing method and arrangement. According to an aspect of the invention, there is provided an RF testing method of an electronic device in conjunction with production of the electronic devices. The method comprises: measuring at least one RF property of the electronic device under test using at least one sensor outputting at least one measurement signal, performing comparison between the at least one measurement signal and at least one corresponding reference signal, and determining defectiveness of the electronic device based on the comparison.

According to another aspect of the invention, there is provided an RF testing method of a mobile phone in conjunction with production of the mobile phones. The method comprises: measuring at least one RF property of the mobile phone under test using at least one sensor outputting at least one measurement signal, performing comparison between the at least one measurement signal and at least one corresponding reference signal, and determining defectiveness of the mobile phone based on the comparison.

According to an aspect of the invention, there is provided an RF testing arrangement of an electronic device in conjunction with production of the electronic devices. The arrangement comprises: at least one sensor outputting at least one measurement signal relating to at least one RF property of the electronic device under test, a reference supply for providing at least one reference signal, a comparator for performing comparison between the at least one measurement signal and at least one corresponding reference signal, and a decision unit for determining defectiveness of the electronic device based on the comparison.

Moreover, according to an aspect of the invention, there is provided an RF testing arrangement of a mobile phone in conjunction with production of the mobile phones. The arrangement comprises: at least one sensor outputting at least one measurement signal relating to at least one RF property of the mobile phone under test, a reference supply for providing at least one reference signal, a comparator for performing comparison between the at least one measurement signal and at least one corresponding reference signal, and a decision unit for determining defectiveness of the mobile phone based on the comparison.

Preferred embodiments of the invention are described in the dependent claims.

The method and arrangement of the invention provide several advantages. By testing the forms of the measurement signals, the behaviour of the electronic device can be tested accurately. Testing is simple, and the signal analysis can be performed with a low processing power. Thus, the testing device will be cheap and easy to use. The total testing time can also be kept short because the analysis of the measured signal can be performed simultaneously with the measurement.

### LIST OF DRAWINGS

In the following, the invention will be described in greater detail with reference to the preferred embodiments and the accompanying drawings, in which

FIG. 1 illustrates a measurement arrangement,

FIG. 2 illustrates a configuration for recording reference signals,

FIG. 3 illustrates the measurement configuration,

FIG. 4 illustrates measured signals,

FIG. 5 illustrates reference signals, and

FIG. 6 illustrates the flow chart of the method.

### DESCRIPTION OF EMBODIMENTS

The present solution is suitable for testing an electronic device. The electronic device may also comprise optoelectronic components. The device may be such as a phone, a mobile phone, a computer, a modul or a card of a computer (such as PCMCIA), digital camera, PDA, a semiproduct etc., but the present solution is not restricted to these, however.

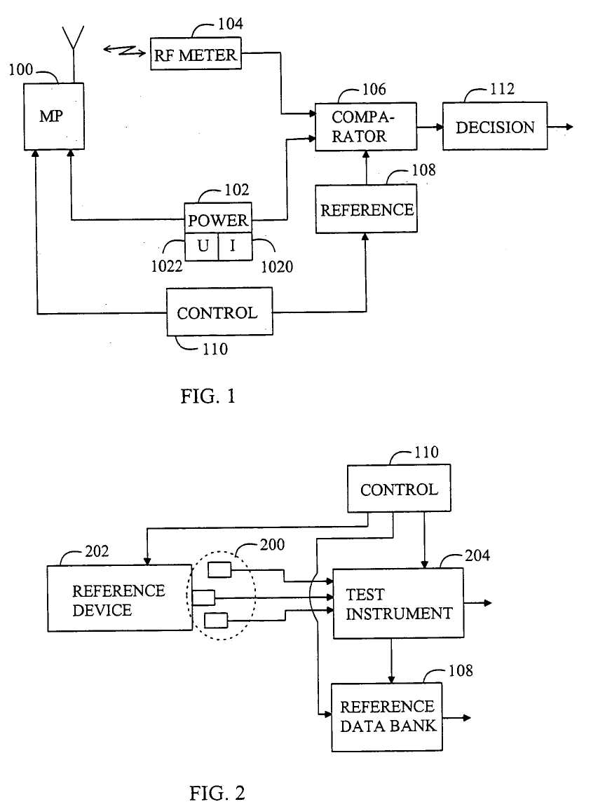

FIG. 1 shows a basic measurement arrangement in which the electronic device 100 is assumed to be a mobile phone. The electronic device 100 is placed in a testing arrangement, which can comprise a power supply 102 with meters 1020, 1022 for measuring voltage and current fed to the electronic device 100, a sensor 104 for measuring at least one signal output by the electronic device 100, a comparator 106 for comparing at least one measurement signal and at least one reference signal, a reference supply 108 for supplying at least one reference signal, a controller 110 and a decision unit 112. Both the meters 1020, 1022 and the sensor 104 output measurement signals. The electronic device may be connected to the power supply 102.

The testing of the electronic device 100 takes place in conjunction with production of the electronic devices 100, i.e. before selling the electronic device. That is why the electronic device 100 may be automatically or manually moved to the testing arrangement in the production line. The testing arrangement may be a fixed part or a separate section of the production line.

During testing, the electronic device 100 is measured using at least one sensor outputting at least one measurement signal. The sensor can be, for example, the sensor 104 for measuring at least one signal output by the electronic device 100. Particularly, if the electronic device 100 is a mobile phone, the sensor 104 can be an RF meter, which can detect the radio frequency radiation transmitted by the mobile phone enabling the determination of the output power of the electronic device 100. Usually the other sensors are the meters 1020, 1022 measuring the input voltage and current for the electronic device 100 enabling the determination of the input power. The behaviour of the input power and the output power can then be compared with the corresponding references or with each other by setting signal forms instead of single signal values against each other. Generally, the comparator 106 performs comparison between at least one measurement signal and at least one corresponding reference signal in the present solution. The comparison of input power and output power can give a piece of additional information. The decision unit 112 can determine the defectiveness of the electronic device based on the comparison. If the defectiveness of the electronic device is too high, it is not accepted to be delivered further. In the desired case, i.e. usually when the electronic device is not defected, it is accepted and delivered further.

The measurement can also be performed in more than one state of the electronic device. The state of the electric device refers to different power levels, frequency bands, modes of operation, self test, configuration or programming of the device, calibration, tuning, modes of transmission, reception, operations etc. The calibration and tuning may refer to measurement and adjustment of frequency, power, I/Q balance (Inphase, Quadrature) and tuning of filters. In more detail, the calibration may refer to transmitter frequency tuning, transmitter power calibration, transmitter power versus channel compensation, receiver AGC (Automatic Gain Control) calibration, receiver LNA (Low Noise Amplifier) calibration, receiver RSSI (Received Signal Strength Indicator) calibration, receiver I/Q-balance calibration, receiver DC-balance calibration, duplex filter tuning, IF (Intermediate Frequency) filter tuning, channel filter tuning, ADC and DAC calibration, local oscillator calibration, temperature sensor calibration, battery sensor calibration, phone clock oscillator calibration, audio frequency response calibration or any combination of these. The present solution is not, however, restricted to these but can be used in other applications, too.

During a continuous measurement, the electronic device can be made to proceed sequentially from state to state in a known manner. The sequence of the measurement can be compared to the corresponding reference sequence. The measurement sequences in the electronic device 100 can be controlled and synchronized by the controller 110.

FIG. 2 shows the recording of the at least one reference signal in the reference supply 108. A reference electronic device 202, which has been verified to operate as desired, is placed in the location for the device to be tested. The verification of the reference electronic device can be based on measurements and calibration. The reference electronic device 202 may be called a golden phone when mobile phones are tested, and it can operate properly or it may have at least one desired and well-defined defect. At least one sensor in the sensor configuration 200 outputs at least one measurement signal measured from the reference electronic device 202, and the measurement signal or signals can be fed to a test instrument 204, which converts and filters the signal or signals to a digital form. The test instrument 204 is not necessarily needed if the sensor configuration 200 can provide suitable signals to the reference supply 108. The test instrument 204 can be a digital signal processor. A desired group of digital signals is then stored in the reference supply 108. The sensor configuration 200 and the test instrument 204 correspond to the meter 104 and sensors 1020, 1022 in FIG. 1. The reference supply 108 can be an electronic memory storing data in a digital form. The controller 110 can control the operation and states of the reference electric device 202 and the operation of the reference supply 108 in order to synchronize the measurements. The controller 110 may also control the operations of the sensor configuration 200 and the test instrument 204.

When the controller 110 drives the reference electronic device 202 into a known state or into a sequence of known states, the at least one sensor 200 detects at least one signal related to the reference electronic device 202. A sensor can have, for example, a bed of nails, an antenna, an optic sensor, a camera, an acoustic sensor or the like, and thus, the sensor may have a galvanic contact to a desired part of the reference electronic device, or the sensor can perform a remote measurement using electromagnetic radiation radiated or reflected from the reference electronic device 202. A non-contact measurement can also be accomplished using acoustic waves, such as audio signals of buttons or keyboard. At least the one measurement signal output by at least the one sensor converted from analog to digital in the test instrument 204 is stored in the reference supply 108 to be used as at least one reference signal during measuring the electronic device during production. Results of many reference electronic devices with or without defects can be stored in the reference supply 108. Instead of reference signals from a reference electronic device verified to operate in a desired manner, reference signals from a signal generator or from a simulator can be used.

In a production line it is possible to perform the reference measurement once at the beginning of the production or every now and then when the production is interrupted. It is also possible to perform the reference measurement such that, for instance, every N^{th} electronic device is a reference electronic device, where N is a positive integer greater than 1, for example 100. In this way the reference can be updated continuously. This is also useful when different kinds of electronic devices are produced. A proper reference is automatically introduced for a new device.

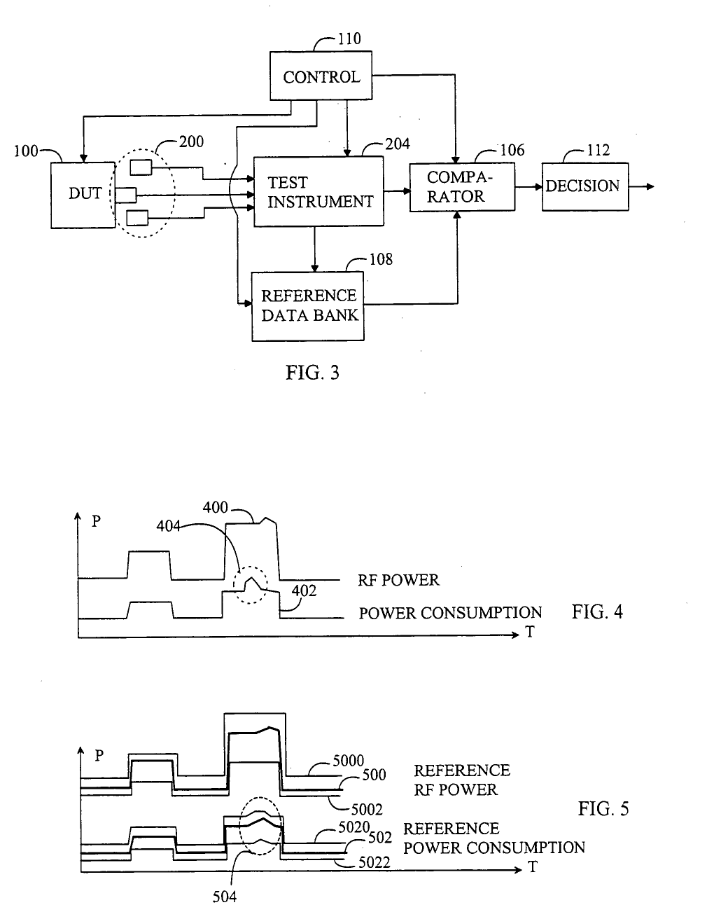

FIG. 3 shows the general measurement arrangement. The electronic device 100 is situated in the testing arrangement. At least one sensor in the sensor configuration 200 outputs at least one measurement signal measured from the electronic device 100, and the measurement signal or signals can be fed to a test instrument 204, which converts and filters signal or signals to a digital form. However, the test instrument 204 is not necessarily needed if the sensor configuration 200 can provide suitable signals for the comparator 106.

When the controller 110 drives the electronic device 202 into a known state or into a sequence of known states, the at least one sensor 200 detects at least one signal related to the reference electronic device 202. The at least one measurement signal output by the at least one sensor and converted from analog to digital in the test instrument 204 is fed to a comparator 106. At least one corresponding reference signal is also fed from the reference supply 108, which is the data base of reference signals, to the comparator 106, which performs a comparison between at least the one measurement signal and at least the one corresponding reference signal. The comparison measures similarity between the compared signals, which can be based on correlation, covariance or any other suitable statistical method. The controller 110 can control the comparison such that the signals to be compared are synchronized to each other. The comparison may also utilize a sliding window principle where the two compared series of samples of known lengths are shifted in relation to each other in order to find out the maximum similarity. The maximum correlation may be used as a measure of the similarity.

The reference signal can represent the electronic device without defects or the electronic device with at least one defect. If the defect in the reference electronic device is known, the decision unit 112 can use it to determine the type of the defect in the electronic device under test.

When the reference signal represents the electronic device without defects, the defectiveness of the electronic device may be determined as acceptable in the decision unit 112, if the similarity is higher than a predetermined threshold. On the other hand, the defectiveness of the electronic device may be determined as unacceptable in the decision unit 112, if the similarity is the same as or lower than a predetermined threshold.

When the reference signal represents an electronic device with at least one defect, the defectiveness of the electronic device may be determined as unacceptable in the decision unit 112, if the similarity is the same as or higher than a predetermined threshold. Correspondingly, if the similarity is lower than the predetermined threshold, the defectiveness of the electronic device may be determined as acceptable in the decision unit 112. The type of fault may also be determined. For example, a missing or faulty capacitor in a certain part of a circuit board can cause a known error in the measurement signal. The reference signal may imitate a known defect and if the similarity between the measurement signal and the reference is high enough, the known defect can be considered the cause of the defect in the measurement signal.

The comparator 106 can form a comparison factor, which measures similarity between the compared signals in the comparison. In the case where at least the one reference signal represents a proper operation electronic device, the defectiveness of the electronic device may be determined as acceptable, if the comparison factor has a higher value than a predetermined threshold value, and the defectiveness of the electronic device may be determined as unacceptable, if the comparison factor has the same value as a predetermined value or a lower value than the predetermined threshold value.

In the case where at least the one reference signal represents a faulty operation of the electronic device, the defectiveness of the electronic device may be determined as unacceptable, if the comparison factor has the same value as a predetermined threshold value or a higher value than the predetermined threshold value, and the defectiveness of the electronic device may be determined as acceptable, if the comparison factor has a lower value than the predetermined threshold value. The type of fault may also be determined.

If the comparison is performed as a correlation, the threshold value in various circumstances can have a single value, for example, 0.8 or some other value found useful. The threshold value for a comparison including a reference signal with a defect may be different from a comparison including a reference signal without a defect. The acceptability of an electronic device can also be based on a combination of comparisons including both the signals with and without defects. The combination can be, for example, an addition or a multiplication of the correlation values.

The comparator 106 may also compare two or more measurement signals. For instance, the measured transmission power of a mobile phone can be compared to the measured power consumption. Too high a difference may indicate a defect.

To be able to measure the electronic device, the device must have contacts for measurements needing galvanic connections, such as voltage and current measurements, or for control operation during measurements.

The RF tests may include measurements of such as signal power, spectrum, frequency, modulation quality (vector errors), sensitivity of a receiver, selectivity of a receiver, immunity to disturbance of a receiver, operation at different power levels, signal quality, such as bit error rate, establishment of a connection (protocols, synchronization with a data network, etc.).

Some of the other possible test measurements are audio measurements, measurements of analog signals, measurements of digital signals, optical measurements and mechanical measurements.

The acoustic tests may include measurements of such as amplification, microphone, loudspeaker, quality of acoustic signals fed from a signal generator to the electronic device, impulse response, distortion, power, etc.

The test of analog signals may include measurements of such as operational voltage, operational current, voltage of a signal, emissions of interference, etc.

The testing of digital signals may include comparing signals, waveforms, clock signal (spectrum, jitter or the like) etc. The testing may also include generating test signals and checking the response of the electronic device to them.

The optical tests may include checking one or more of the following: indicator light when driven on and off, assembly of the device, optical connections etc. The assembly of the electronic device can be checked using a camera and an intelligent machine vision system in the testing arrangement.

Mechanically the electronic device can be tested using a robot, which, for example, presses the keyboard or other buttons. When a key is pressed signals in the electronic device can be measured. At the same time states of the possible indicator lights, such as leds, can be detected or an image of the display can be formed in order to compare it with a reference image.

FIG. 4 illustrates signals measured from a mobile phone as an example of measurement signals. The Y-axis represents the power in an arbitrary scale and the x-axis represents the time in an arbitrary scale. Line 400 shows behaviour of measured radio frequency power radiated from a mobile phone during a controlled sequence through various power levels, which represent states of the electronic device. Line 402 shows behaviour of measured power consumption during the same period of time. The similarity is clear, but there is also a difference. There is no peak in the radiated power (line 400) resembling the peak 404 in the power consumption.

FIG. 5 shows the reference signals corresponding to the measured signals in FIG. 4. Line 500 represents a reference for the radiated power when the mobile phone has no defects. The reference 500 may have an upper border 5000 and a lower border 5002 within which the measured signal must remain in order to have a high enough similarity with the reference. Line 502 represents a reference for the consumed power when the mobile phone has a defect, which manifests itself as a peak 504 in line 500. Line 502 may also have an upper border 5020 and a lower border 5022 within which the measured signal must remain in order to have a high enough similarity with the reference. The borders can be understood as kinds of thresholds related to the correlation. However, the actual threshold of the comparison cannot be shown in FIG. 5. If the defect causing the peak 504 is known, the same fault can be expected to explain the peak 404 in the electronic device under test.

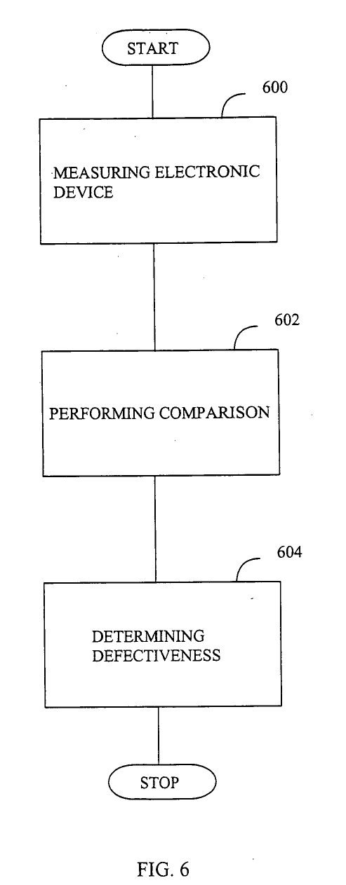

FIG. 6 illustrates the main steps of the present method as a flow chart. In step 600 the electronic device is measured using at least one sensor outputting at least one measurement signal. In step 602 a comparison between the at least one measurement signal and at least one corresponding reference signal is performed. In step 604 defectiveness defining the acceptability of the electronic device is determined based on the comparison.

Even though the invention is described above with reference to an example according to the accompanying drawings, it is clear that the invention is not restricted thereto but it can be modified in several ways within the scope of the appended claims.

1. An RF testing method of an electronic device in conjunction with production of the electronic devices, the method comprising:
measuring at least one RF property of the electronic device under test using at least one sensor outputting at least one measurement signal,
performing comparison between the at least one measurement signal and at least one corresponding reference signal, and
determining defectiveness of the electronic device based on the comparison.

2. The method of claim 1, further comprising
changing the states of the electronic device sequentially, and
performing comparison between the at least one measurement signal and the at least one corresponding reference signal related to the sequences of the states of the electronic device.

3. The method of claim 1, further comprising
performing comparison between at least one measurement signal and at least one corresponding reference signal representing an electronic device without defects, the comparison measuring similarity between the compared signals,
determining the defectiveness of the electronic device as acceptable, if the similarity is higher than a predetermined threshold, and
determining the defectiveness of the electronic device as unacceptable, if the similarity is the same as the predetermined threshold or lower than the predetermined threshold.

4. The method of claim 3, further comprising
forming a comparison factor measuring similarity between the compared signals in the comparison,
determining the defectiveness of the electronic device as acceptable, if the comparison factor has a higher value than a predetermined threshold value, and
determining the defectiveness of the electronic device as unacceptable, if the comparison factor has the same value as a predetermined value or a lower value than the predetermined threshold value.

5. The method of claim 1, further comprising
performing comparison between the at least one measurement signal and at least one corresponding reference signal representing an electronic device with at least one defect, the comparison measuring similarity between the compared signals,
determining the defectiveness of the electronic device as unacceptable, if the similarity is the same as a predetermined threshold or higher than the predetermined threshold, and
determining the defectiveness of the electronic device as acceptable, if the similarity is lower than the predetermined threshold.

6. The method of claim 5, further comprising
forming a comparison factor measuring similarity between the compared signals in the comparison,
determining the defectiveness of the electronic device as unacceptable, if the comparison factor has the same value as a predetermined threshold value or a higher value than the predetermined threshold value, and
determining the defectiveness of the electronic device as acceptable, if the comparison factor has a lower value than the predetermined threshold value.

7. The method of claim 5, further comprising
using a reference signal representing an electronic device with at least one known defect, and
determining the type of defect in the electronic device according to the at least one known defect.

8. The method of claim 1, further comprising
comparing at least two measurement signals for determining defectiveness of the electronic device.

9. The method of claim 1, further comprising at least one measurement of the following: measuring audio, measuring analog signaling, measuring digital signaling, measuring optical signaling and mechanical measurements, the measurement performed by at least one sensor outputting at least one measurement signal,
performing comparison between the at least one measurement signal and at least one corresponding reference signal, and
determining defectiveness of the electronic device based on the comparison.

10. An RF testing method of a mobile phone in conjunction with production of the mobile phones, the method comprising:
measuring at least one RF property of the mobile phone under test using at least one sensor outputting at least one measurement signal,
performing comparison between the at least one measurement signal and at least one corresponding reference signal, and
determining defectiveness of the mobile phone based on the comparison.

11. An RF testing arrangement of an electronic device in conjunction with production of the electronic devices, the arrangement comprising:
at least one sensor outputting at least one measurement signal relating to at least one RF property of the electronic device under test,
a reference supply for providing at least one reference signal,
a comparator for performing comparison between the at least one measurement signal and at least one corresponding reference signal, and
a decision unit for determining defectiveness of the electronic device based on the comparison.

12. The arrangement of claim 11, further comprising
a controller for changing the states of the electronic device sequentially, the comparator being configured to perform the comparison between the at least one measurement signal and the at least one corresponding reference signal related to the sequences of the states of the electronic device.

13. The arrangement of claim 11, wherein the comparator is configured to perform the comparison measuring similarity between the at least one measurement signal and the at least one corresponding reference signal representing an electronic device without defects,
the decision unit is configured to determine the defectiveness of the electronic device as acceptable, if the similarity is higher than a predetermined threshold, and
the decision unit is configured to determine the defectiveness of the electronic device as unacceptable, if the similarity is the same as the predetermined threshold or lower than the predetermined threshold.

14. The arrangement of claim 13, wherein the comparator is configured to form a comparison factor measuring similarity between the compared signals,
the decision unit is configured to determine the defectiveness of the electronic device as acceptable, if the comparison factor has a higher value than a predetermined threshold value, and
the decision unit is configured to determine the defectiveness of the electronic device as unacceptable, if the comparison factor has the same value as a predetermined value or a lower value than the predetermined threshold value.

15. The arrangement of claim 11, wherein the comparator is configured to perform the comparison measuring similarity between the at least one measurement signal and at least one corresponding reference signal representing an electronic device with at least one defect,
the decision unit is configured to determine the defectiveness of the electronic device as unacceptable, if the similarity is the same as a predetermined threshold or higher than the predetermined threshold, and
the decision unit is configured to determine the defectiveness of the electronic device as acceptable, if the similarity is lower than the predetermined threshold.

16. The arrangement of claim 15, wherein the comparator is configured to form a comparison factor measuring similarity between the compared signals in the comparison,
the decision unit is configured to determine the defectiveness of the electronic device as unacceptable, if the comparison factor has the same value as a predetermined threshold value or a higher value than the predetermined threshold value, and
the decision unit is configured to determine the defectiveness of the electronic device as acceptable, if the comparison factor has a lower value than the predetermined threshold value.

17. The arrangement of claim 15, wherein the reference supply is configured to provide a reference signal representing an electronic device with at least one known defect, and the decision unit is configured to determine the type of defect in the electronic device according to the at least one known defect.

18. The arrangement of claim 11, wherein the comparator is configured to compare at least two measurement signals for determining defectiveness of the electronic device.

19. The arrangement of claim 11, wherein at least one sensor is configured to perform at least one measurement of the following: measuring audio, measuring analog signaling, measuring digital signaling, measuring optical signaling and mechanical measurements, and output at least one measurement signal,
the reference supply is configured to provide at least one corresponding reference signal,
the comparator is configured to perform comparison between the at least one measurement signal and at least one corresponding reference signal, and
the decision unit is configured to determine defectiveness of the electronic device based on the comparison.

20. An RF testing arrangement of a mobile phone in conjunction with production of the mobile phones, the arrangement comprising:
at least one sensor outputting at least one measurement signal relating to at least one RF property of the mobile phone under test,
a reference supply for providing at least one reference signal,
a comparator for performing comparison between the at least one measurement signal and at least one corresponding reference signal, and
a decision unit for determining defectiveness of the mobile phone based on the comparison.
